(19) United States
(12) Patent Application Publication
(10) Pub. No.: US 2025/0095985 A1
(43) Pub. Date: Mar. 20, 2025

(54) FILM FORMING METHOD AND FILM FORMING APPARATUS

(71) Applicant: Tokyo Electron Limited, Tokyo (JP)

(72) Inventors: Tomohiro NAKAGAWA, Yamanashi (JP); Yumiko KAWANO, Yamanashi (JP); Shuji AZUMO, Yamanashi (JP)

(21) Appl. No.: 18/964,075

(22) Filed: Nov. 29, 2024

Related U.S. Application Data
(63) Continuation of application No. PCT/JP2023/020227, filed on May 31, 2023.

(30) Foreign Application Priority Data
Jun. 14, 2022 (JP) 2022-095858

(51) Int. Cl. H01L 21/02; C23C 16/52

(52) U.S. Cl. CPC H01L 21/0228; C23C 16/52; H01L 21/02164; H01L 21/02274; H01L 21/02304

(57) ABSTRACT

Film forming method of present disclosure's embodiment is method for forming silicon oxide film on substrate, and includes: (a) preparing substrate having on surface thereof first region where insulating film is exposed and second region where conductive film is exposed; (b) selectively forming inhibiting layer inhibiting silicon oxide film formation on second region; (c) forming silicon oxide film on first region while inhibiting silicon oxide film formation on second region by inhibiting layer; and (d) reforming silicon oxide film formed on first region. (c) includes (c1) supplying metal catalyst gas to surface and adsorbing it to first region; and (c2) supplying silanol-containing gas to surface to react it with metal catalyst gas adsorbed to first region to form silicon oxide film. (d) includes: (d1) exposing surface to plasma formed from hydrogen gas-containing first gas; and (d2) exposing surface to plasma formed from second gas containing inert gas without hydrogen gas.

### CROSS-REFERENCE TO RELATED APPLICATIONS

This application is a continuation application of International Application No. PCT/JP2023/020227, filed on May 31, 2023, and designating the U.S., which is based upon and claims priority to Japanese Patent Application No. 2022-095858, filed on Jun. 14, 2022, the entire contents of which are incorporated herein by reference.

### BACKGROUND

### Technical Field

The present disclosure relates to a film forming method and a film forming apparatus.

### Background Art

A technique for selectively forming a silicon oxide film on an exposed surface of an insulating film on a substrate having a surface to which a conductive film and the insulating film are exposed is known (see, e.g., Japanese Patent Application Laid-Open No. 2019-52142, Japanese Patent Application Laid-Open No. 2019-96881, and U.S. Patent Application Publication No. 2021/301392).

### SUMMARY

The present disclosure provides a technique for selectively forming a silicon oxide film having desired electrical characteristics on an insulating film.

A film forming method for forming a silicon oxide film on a substrate according to an embodiment of the present disclosure includes: (a) preparing a substrate having on surface thereof a first region where an insulating film is exposed and a second region where a conductive film is exposed; (b) selectively forming an inhibiting layer for inhibiting formation of the silicon oxide film on the second region; (c) forming the silicon oxide film on the first region while inhibiting formation of the silicon oxide film on the second region by the inhibiting layer; and (d) reforming the silicon oxide film formed on the first region, wherein the (c) includes: (c1) supplying a metal catalyst gas to the surface and adsorbing the metal catalyst gas to the first region; and (c2) supplying a silanol-containing gas to the surface to react the silanol-containing gas with the metal catalyst gas adsorbed to the first region to form the silicon oxide film, and the (d) includes: (d1) exposing the surface to a plasma formed from a first gas containing hydrogen gas; and (d2) exposing the surface to a plasma formed from a second gas containing no hydrogen gas and containing an inert gas.

According to the present disclosure, a silicon oxide film having desired electrical characteristics can be selectively formed on an insulating film.

### BRIEF DESCRIPTION OF THE DRAWINGS

FIG. 1 is a flowchart illustrating a film forming method according to an embodiment;

FIG. 2A is a cross-sectional view illustrating a film forming method according to an embodiment;

FIG. 2B is a cross-sectional view illustrating a film forming method according to an embodiment.

FIG. 2C is a cross-sectional view illustrating a film forming method according to an embodiment;

FIG. 2D is a cross-sectional view illustrating a film forming method according to an embodiment;

FIG. 3 is a flowchart illustrating an example of step S5;

FIG. 4 is a flowchart illustrating an example of a reforming process;

FIG. 5 is a diagram illustrating an example of a processing system for performing a film forming method according to an embodiment;

FIG. 6 is a diagram illustrating an example of a film forming apparatus for performing a film forming method according to an embodiment;

FIG. 7 is a drawing illustrating measurement results of a leakage current of a silicon oxide film.

FIG. 8 is a drawing illustrating a measurement result of an infrared absorption spectrum of a silicon oxide film;

FIG. 9 is a drawing illustrating a measurement result of an infrared absorption spectrum of a silicon oxide film; and

FIG. 10 is a drawing illustrating measurement results of an infrared absorption spectrum of a silicon oxide film.

### DETAILED DESCRIPTION OF THE INVENTION

Hereinafter, non-limiting exemplary embodiments of the present disclosure will be described with reference to the accompanying drawings. In all of the accompanying drawings, the same or corresponding members or parts are denoted by the same or corresponding reference numerals, and repeated explanations will be omitted.

### Silicon Oxide Film

Hitherto, it is known to form an AlO film as an insulating film when selectively forming an insulating film on an exposed surface of an insulating film on a substrate having a surface to which the insulating film and a conductive film are exposed. An AlO film has a relatively high dielectric constant. Therefore, use of AlO films as interlayer insulating films makes the capacitance between the wiring higher as semiconductor devices become smaller, leading to RC delay. Moreover, as an insulating film used for a Fully Self-Aligned Via (FSAV), a film having a dielectric constant lower than that of an AlO film is required as well. Therefore, a silicon oxide film having a low dielectric constant has been studied. Hereinafter, a method of selectively forming a silicon oxide film on an exposed surface of an insulating film on a substrate having a surface to which the insulating film and a conductive film are exposed will be described.

### Film Forming Method

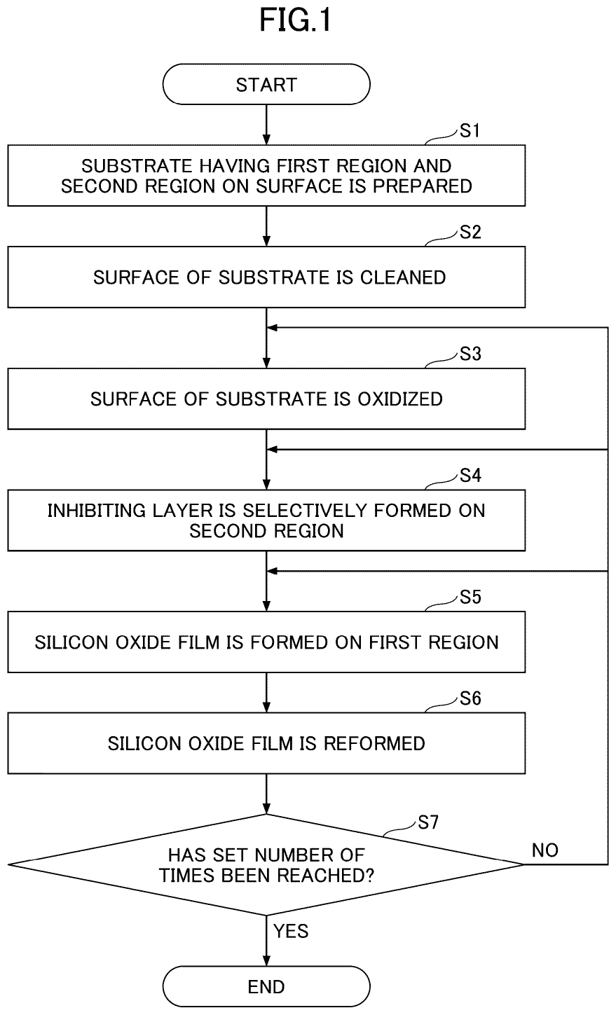

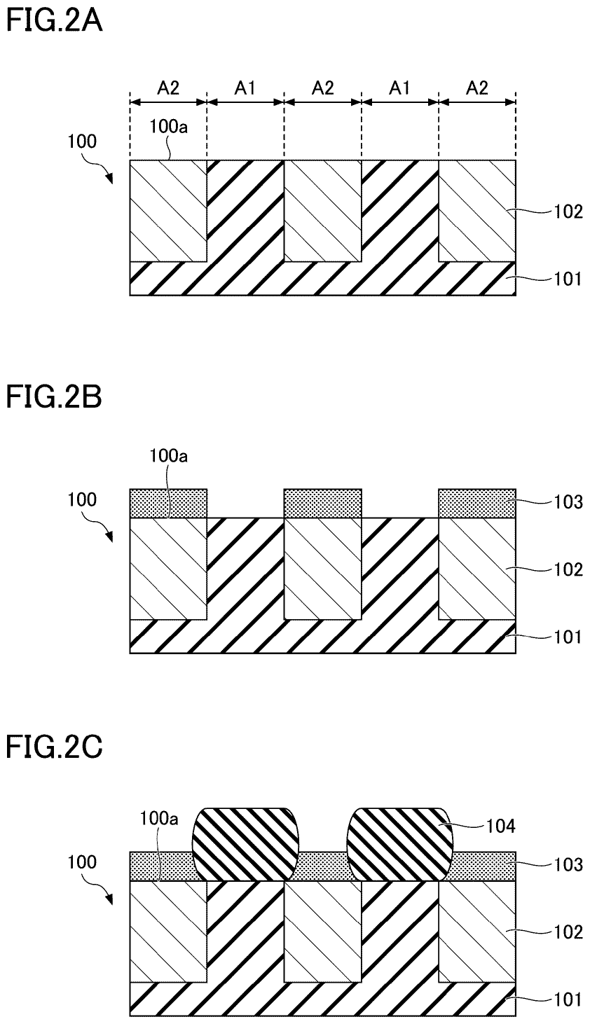

A film forming method according to an embodiment will be described with reference to FIGS. 1, 2A, 2B, 2C, and 2D. The film forming method according to the embodiment includes steps S1 to S7 illustrated in FIG. 1.

In step S1, as illustrated in FIG. 2A, a substrate 100 having on its surface 100a, a first region A1 where an insulating film 101 is exposed and a second region A2 where a conductive film 102 is exposed is prepared.

The insulating film 101 is, for example, an interlayer insulating film. The interlayer insulating film is preferably a low-k film. The insulating film 101 is not particularly limited, and may be, for example, a SiO film, a SiN film, a SiOC film, a SiON film, or a SiOCN film. The SiO film means a film containing silicon (Si) and oxygen (O). The atomic ratio of Si to O in the SiO film is not limited to 1:1. The same applies to the SiN film, the SiOC film, the SiON film, and the SiOCN film. The insulating film 101 has recesses in its surface. The recesses are, for example, trenches, contact holes, or via holes.

The conductive film 102 is filled in the recesses. The conductive film 102 is not particularly limited, and is, for example, a Cu film, a Co film, a Ru film, or a W film.

The substrate 100 may further include a barrier film. The barrier film is formed along the inner surface of the recesses. The barrier film is formed between the insulating film 101 and the conductive film 102. The barrier film inhibits metal diffusion from the conductive film 102 to the insulating film 101. The barrier film is not particularly limited, and is, for example, a TaN film or a TiN film. The TaN film means a film containing tantalum (Ta) and nitrogen (N). The atomic ratio of Ta to N in the TaN film is not limited to 1:1. The same applies to the TiN film.

In step S2, the surface 100a of the substrate 100 is cleaned. For example, in step S2, a reducing gas such as hydrogen (H₂) gas is supplied to the surface 100a of the substrate 100 to remove a natural oxide film formed on the surface 100a of the substrate 100. The natural oxide film is formed on the surface of the conductive film 102, for example. In step S2, a plasma may be formed from the reducing gas. The reducing gas may be mixed with a rare gas such as argon (Ar) gas and the like. In step S2, for example, the substrate 100 is heated to 120° C. or higher and 200° C. or lower. Step S2 may be omitted.

In step S3, the surface 100a of the substrate 100 is oxidized. For example, in step S3, an oxygen-containing gas such as oxygen (O₂) gas is supplied to the surface 100a of the substrate 100 to oxidize the surface of the conductive film 102 adequately. Since the natural oxide film is removed in advance, the density of oxygen atoms becomes a desired density. As a result, in step S4 described later, a dense inhibiting layer 103 (for example, a Self-Assembled Monolayer (SAM)) can be formed on the surface of the conductive film 102. In step S3, for example, the substrate 100 is heated to 120° C. or higher and 200° C. or lower. Step S3 may be omitted.

In step S4, as illustrated in FIG. 2B, an inhibiting layer 103 for inhibiting formation of a silicon oxide film 104 described later is selectively formed on the second region A2. The inhibiting layer 103 is formed of, for example, a SAM. For example, in step S4, an organic compound containing fluorine as a raw material of the SAM is supplied to the surface of the substrate 100, and the SAM is selectively formed on the second region A2 of the first region A1 and the second region A2. In step S3, for example, the substrate 100 is heated to 120° C. or higher and 200° C. or lower. The raw material of the SAM is not particularly limited, and is, for example, a thiol-based compound.

The thiol-based compound has hydrogenated sulfur as a head group and is represented by a general formula “R—SH”. R is, for example, a hydrocarbon group in which at least a part of hydrogen is replaced with fluorine. Specific examples of the thiol-based compound include CF₃(CF₂)₅CH₂CH₂SH(1H,1H,2H,2H-perfluorooctanethiol: PFOT) and CF₃(CF₂)₇CH₂CH₂SH(1H,1H,2H,2H-perfluorodecanethiol: PFDT).

The thiol-based compound is more easily chemically adsorbed to the conductive film 102 than to the insulating film 101. In a case where the insulating film 101 is exposed in the first region A1 and the conductive film 102 is exposed in the second region A2, the SAM is selectively formed on the second region A2 out of the first region A1 and the second region A2.

The raw material of the SAM is not limited to the thiol-based compound. For example, the raw material of the SAM may be a phosphonic acid-based compound. The phosphonic acid-based compound is represented by a general formula “R—P(═O)(OH)₂”. R is, for example, a hydrocarbon group in which at least a part of hydrogen is replaced with fluorine.

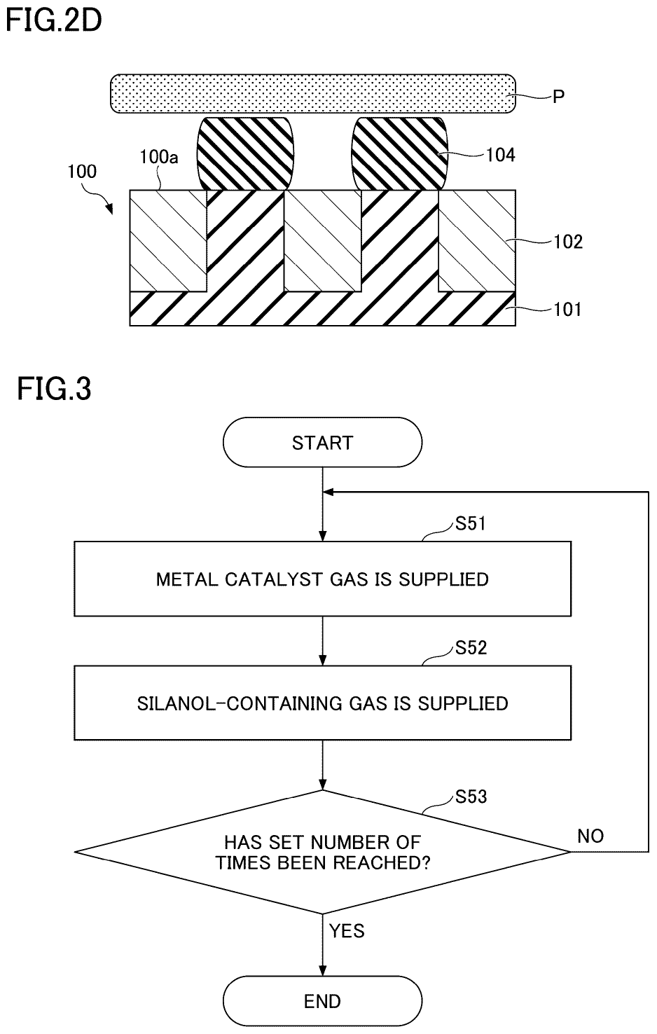

In step S5, as illustrated in FIG. 2C, a silicon oxide film 104 is formed on the first region A1 while inhibiting formation of the silicon oxide film 104 on the second region A2 by the inhibiting layer 103. The silicon oxide film 104 is formed, for example, by chemical vapor deposition (CVD). Step S5 includes, for example, steps S51 to S53 illustrated in FIG. 3.

In step S51, a metal catalyst gas is supplied to the surface 100a of the substrate 100 to selectively adsorb the metal catalyst gas to the first region A1. The metal catalyst gas is, for example, trimethylaluminum (TMA) gas. In step S51, the substrate is heated to, for example, 120° C. or higher and 300° C. or lower.

In step S52, a silanol-containing gas is supplied to the surface 100a of the substrate 100, and the silanol-containing gas is reacted with the metal catalyst gas adsorbed to the first region A1 to form the silicon oxide film 104. The silanol-containing gas is, for example, Tris(tert-pentoxy) silanol (TPSOL) or Tris(tert-butoxy) silanol (TBSOL). In step S52, for example, the substrate 100 is heated to 120° C. or higher and 300° C. or lower.

Although TMA adsorbs to the insulating film 101 having OH groups, but is inhibited from adsorbing to the inhibiting layer 103. Since the silanol-containing gas reacts with the adsorbed TMA to advance film formation, a silicon oxide film is selectively formed on the insulating film 101.

In step S53, it is determined whether steps S51 to S52 have been performed a number of times that is set. In a case where the number of times the steps have been performed has not reached the set number (NO in step S53), steps S51 to S52 are performed again. On the other hand, in a case where the number of times the steps have been performed has reached the set number (YES in step S53), since the film thickness of the silicon oxide film 104 has reached a predetermined film thickness with respect to the plasma processing, the process is terminated. The number of times set in step S53 is set in accordance with the film formation amount such that the silicon oxide film 104 formed in step S5 reaches a predetermined film thickness. The film formation amount can be adjusted in accordance with the supply amount of the silanol-containing gas and the like. The predetermined film thickness is, for example, 2 nm or greater and 5 nm or less. In this case, in step S6, a plasma tends to act across the entirety of the silicon oxide film 104 formed in the immediately preceding step S5 in the film thickness direction. Therefore, the silicon oxide film 104 is reformed across the entirety thereof in the film thickness direction. On the other hand, as the film thickness of the silicon oxide film 104 formed in step S5 increases beyond the predetermined film thickness, it becomes increasingly difficult for the plasma-induced reformation in step S6 to reach deep into the silicon oxide film 104 from the surface thereof. The number of times set in step S53 may be 1 or a plurality of times.

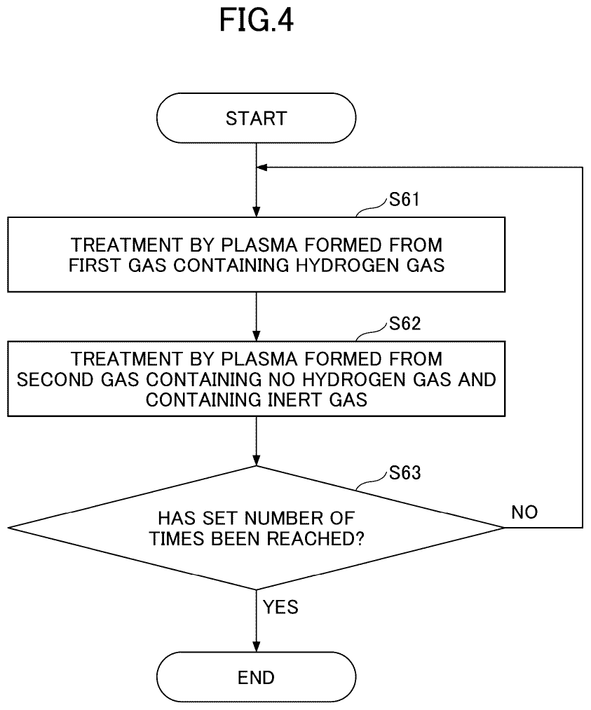

In step S6, as illustrated in FIG. 2D, the surface 100a of the substrate 100 is exposed to a plasma P to reform the silicon oxide film 104 formed on the first region A1. Here, the inhibiting layer 103 is removed. Step S6 includes, for example, steps S61 to S63 illustrated in FIG. 4.

In step S61, the surface 100a of the substrate 100 is exposed to a plasma formed from a first gas containing hydrogen gas. Thus, impurities in the film such as Si—OH bonds are removed. Here, removal of the inhibiting layer 103 also proceeds. In step S61, when the silicon oxide film 104 is exposed to the plasma formed from the first gas, hydrogen defects may be generated in the silicon oxide film 104 due to the reaction between the active species contained in the plasma and the silicon oxide film 104. The first gas may be used while being mixed with an inert gas. The inert gas is, for example, a rare gas such as argon gas.

An example of the processing conditions in step S61 is as follows.
Hydrogen gas flow rate: from 200 sccm to 3,000 sccm
Argon gas flow rate: from 900 sccm to 6,000 sccm
Substrate temperature: from 120° C. to 200° C. Processing pressure: from 1 Torr to 5 Torr (from 133 Pa to 667 Pa)
Processing time: from 10 seconds to 30 seconds

In step S62, the surface of the substrate 100 is exposed to a plasma formed from a second gas containing no hydrogen gas and containing an inert gas. Thus, the hydrogen defects generated in the silicon oxide film 104 in step S61 are removed. As a result, both of impurities such as Si—OH bonds and the hydrogen defects can be reduced, and the leakage current of the silicon oxide film can be further reduced compared with a reformation using only one plasma of either the first gas or the second gas. The inert gas is, for example, a rare gas such as argon gas.

An example of the processing conditions in step S62 is as follows.
Argon gas flow rate: from 600 sccm to 6,000 Sccm
Substrate temperature: from 120° C. to 200° C.
Processing pressure: from 1 Torr to 5 Torr (from 133 Pa to 667 Pa)
Processing time: from 10 seconds to 30 seconds

In step S63, it is determined whether or not steps S61 to S62 have been performed a number of times that is set. In a case where the number of times the steps have been performed has not reached the set number (NO in step S63), steps S61 to S62 are performed again. On the other hand, in a case where the number of times the steps have been performed has reached the set number (YES in step S63), the process ends. The number of times set in step S63 is set in accordance with the film thickness of the silicon oxide film 104 formed in step S5. The number of times set in step S63 may be 1 or a plurality of times. The number of times set is preferably from 2 to 6.

When performing steps S61 and S62 a plurality of times, for example, the plasma may be maintained when switching between step S61 and step S62, or the plasma may be temporarily stopped.

In step S7, it is determined whether steps S5 and S6 have been performed a number of times that is set. In a case where the number of times the steps have been performed has not reached the set number (NO in step S7), steps S5 to S6 are performed again. On the other hand, in a case where the number of times the steps have been performed has reached the set number (YES in step S7), the process is terminated because the film thickness of the silicon oxide film 104 has reached the target film thickness. The number of times set in step S7 is set in accordance with the target film thickness of the silicon oxide film 104. The target film thickness is, for example, 6 nm. The number of times set in step S7 may be 1 or a plurality of times. In a case where the number of times the steps have been performed has not reached the set number in step S7 (NO in step S7), step S4 may be performed again. By performing step S4 again, it is possible to make the inhibiting layer 103 dense, and to improve the inhibiting performance. In a case where the number of times the steps have been performed has not reached the set number in step S7 (NO in step S7), step S3 may be performed again. By performing step S3 again to enhance the adsorptivity of the organic compound that will form the inhibiting layer 103, it is possible to make the inhibiting layer 103 dense, and to improve the inhibiting performance.

As described above, according to the film forming method of the embodiment, the substrate 100 having on its surface the first region A1 where the insulating film 101 is exposed and the second region A2 where the conductive film 102 is exposed is prepared, and the silicon oxide film 104 is selectively formed on the insulating film 101. Next, a cyclic plasma treatment is performed in which a cycle including the step of exposing the silicon oxide film 104 to the plasma formed from the first gas and the step of exposing the silicon oxide film 104 to the plasma formed from the second gas is performed once or a plurality of times. By applying the cyclic plasma treatment to the silicon oxide film 104, it is possible to reduce both impurities such as Si—OH bonds in the film and hydrogen defects. As a result, a leakage current of the silicon oxide film 104 can be reduced. Thus, according to the film forming method of the embodiment, the silicon oxide film 104 having desired electrical characteristics can be selectively formed on the insulating film 101.

It is pertinent to add that, as a method for reforming the silicon oxide film, it is also conceivable to perform an oxidation treatment on the silicon oxide film. However, an oxidation treatment on the silicon oxide film on the substrate 100 having on its surface the first region A1 where the insulating film 101 is exposed and the second region A2 where the conductive film 102 is exposed also brings the conductive film 102 to be oxidized. This is not preferable.

### Processing System

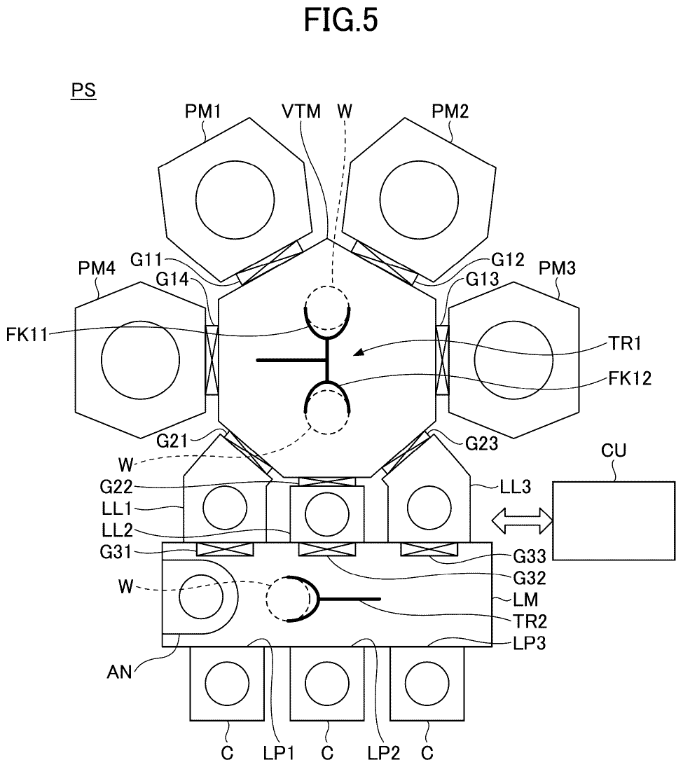

Referring to FIG. 5, an example of a processing system for performing the film forming method according to the embodiment will be described.

The processing system PS includes processing apparatuses PM1 to PM4, a vacuum conveying chamber VTM, load lock chambers LL1 to LL3, an open-air conveying chamber LM, load ports LP1 to LP3, and a total controller CU.

The processing apparatuses PM1 to PM4 are connected to the vacuum conveying chamber VTM via gate valves G11 to G14, respectively. The processing apparatuses PM1 to PM4 are configured such that the interior thereof can be depressurized to a predetermined vacuum atmosphere. The processing apparatuses PM1 to PM4 store a substrate W therein and perform a desired process on it.

The vacuum conveying chamber VTM is configured such that the interior thereof can be depressurized to a predetermined vacuum atmosphere. The vacuum conveying chamber VTM includes a first conveying device TR1 capable of conveying a substrate W in a depressurized state. The first conveying device TR1 conveys the substrate W to the processing apparatuses PM1 to PM4 and the load lock chambers LL1 to LL3. The first conveying device TR1 includes, for example, two independently movable conveying arms FK11 and FK12.

The load lock chambers LL1 to LL3 are connected to the vacuum conveying chamber VTM via gate valves G21 to G23, respectively. The load lock chambers LL1 to LL3 are connected to the open-air conveying chamber LM via gate valves G31 to G33, respectively. The load lock chambers LL1 to LL3 are configured such that the interior thereof can be switched between an open-air atmosphere and a vacuum atmosphere.

The open-air conveying chamber LM has an open-air atmosphere inside. For example, a downflow of a clean air is formed inside the open-air conveying chamber LM. An aligner AN for aligning the substrate W is provided inside the open-air conveying chamber LM. The aligner AN may be provided outside the open-air conveying chamber LM. The open-air conveying chamber LM includes a second conveying device TR2. The second conveying device TR2 conveys the substrate W to the load lock chambers LL1 to LL3, the load ports LP1 to LP3, and the aligner AN.

The load ports LP1 to LP3 are provided on a wall surface on a long side of the open-air conveying chamber LM. Carriers C are attached to the load ports LP1 to LP3. The carriers C include a carrier C containing a substrate W and an empty carrier C. The carriers C may be, for example, Front Opening Unified Pods (FOUP).

The total controller CU may be, for example, a computer. The total controller CU includes a Central Processing Unit (CPU), a Random Access Memory (RAM), a Read Only Memory (ROM), and an auxiliary memory device. The CPU operates based on a program stored in the ROM or the auxiliary memory device, and controls each part of the processing system PS. For example, the total controller CU controls the operations of the processing apparatuses PM1 to PM4, the first conveying device TR1, the second conveying device TR2, the gate valves G11 to G14, G21 to G23, and G31 to G33. For example, the total controller CU controls the operation of switching the interior of the load lock chambers LL1 to LL3 between the open-air atmosphere and the vacuum atmosphere.

Next, the operation of the processing system PS will be described. First, the second conveying device TR2 takes out a substrate W from the carrier C, conveys the taken-out substrates W to the aligner AN, and exits the aligner AN. Next, the aligner AN aligns the substrate W. Next, the second conveying device TR2 takes out the substrate W from the aligner AN, conveys the taken-out substrate W to the load lock chamber LL1, and exits the load lock chamber LL1. Next, the interior of the load lock chamber LL1 is switched from the open-air atmosphere to the vacuum atmosphere. Then, the first conveying device TR1 takes out the substrate W from the load lock chamber LL1, and conveys the taken-out substrate W to the processing apparatus PM1.

Next, the processing apparatus PM1 performs steps S2 to S6 of the film forming method according to the embodiment. Next, the total controller CU determines whether steps S2 to S6 have been performed the set number of times. In a case where the number of times the steps have been performed has not reached the set number, steps S2 to S6 are performed again.

On the other hand, in a case where the number of times the steps have been performed has reached the set number, the first conveying device TRI takes out the substrate W from the processing apparatus PM1, conveys the taken-out substrate W to the load lock chamber LL3, and exits the load lock chamber LL3. Next the interior of the load lock chamber LL3 is switched from the vacuum atmosphere to the open-air atmosphere. Thereafter, the second conveying device TR2 takes out the substrate W from the load lock chamber LL3, and accommodates the taken-out substrate W in the carrier C. Then, the processing of the substrate W is completed.

In the operation of the processing system PS described above, the case of performing steps S2 to S6 using one processing apparatus PM1 has been described, but the present invention is not limited thereto. For example, steps S2 to S6 may be performed using at least one of the other processing apparatuses PM2 to PM4.

For example, steps S2 to S6 may be performed using two or more of the four processing apparatuses PM1 to PM4. For example, step S51 may be performed using the processing apparatus PM1 and step S52 may be performed using the processing apparatus PM2. In this case, since the time required for temperature change in a case of performing steps S51 and S52 at different temperatures can be shortened, productivity can be improved.

### Film Forming Apparatus

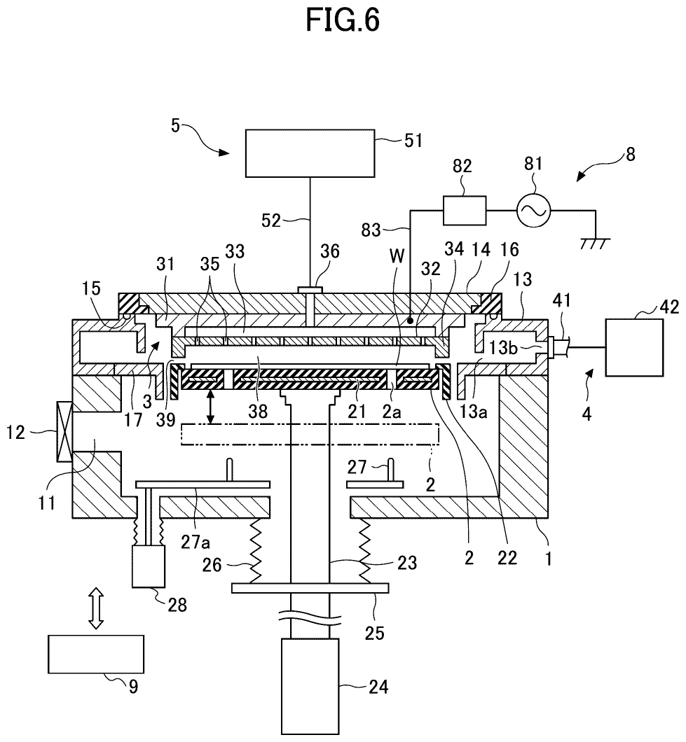

Referring to FIG. 6, an example of a film forming apparatus used as the processing apparatuses PM1 to PM4 included in the processing system PS illustrated in FIG. 5 will be described.

The film forming apparatus includes a processing container 1, a mounting table 2, a shower head 3, a gas exhauster 4, a gas supply 5, an RF power supply 8, and a controller 9.

The processing container 1 is made of a metal such as aluminum and has a substantially cylindrical shape. The processing container 1 accommodates a substrate W. The substrate W may be, for example, a semiconductor wafer. A loading/unloading port 11 for loading or unloading the substrate W is formed on the side wall of the processing container 1. The loading/unloading port 11 is opened and closed by a gate valve 12. An annular gas exhaust duct 13 having a rectangular cross-sectional shape is provided on the main body of the processing container 1. A slit 13a is formed along the inner circumferential surface of the gas exhaust duct 13. A gas exhaust port 13b is formed in the outer wall of the gas exhaust duct 13. A ceiling wall 14 is provided on the upper surface of the gas exhaust duct 13 so as to close the upper opening of the processing container 1 via an insulating member 16. The space between the gas exhaust duct 13 and the insulating member 16 is airtightly sealed with a sealing member 15. The sealing member 15 may be, for example, an O-ring. The partitioning member 17 partitions the interior of the processing container 1 into an upper side and a lower side when the mounting table 2 (and a cover member 22) lifts to a processing position described later.

The mounting table 2 horizontally supports the substrate W in the processing container 1. The mounting table 2 is formed in a disk shape having a size corresponding to the substrate W and is supported by a support member 23. The mounting table 2 is formed of a ceramic material such as AlN or a metal material such as aluminum or a nickel alloy. A heater 21 for heating the substrate W is embedded in the mounting table 2. The heater 21 generates heat by receiving power from a heater power source (not illustrated). A thermocouple (not illustrated) is provided near the upper surface of the mounting table 2. The substrate W is controlled to a predetermined temperature by controlling the output from the heater 21 in accordance with a temperature signal of the thermocouple. The mounting table 2 is provided with the cover member 22 made of ceramics such as alumina so as to cover the outer peripheral region of the upper surface of the mounting table and the side surface of the mounting table.

The support member 23 for supporting the mounting table 2 is provided on the bottom surface of the mounting table 2. The support member 23 extends from the center of the bottom surface of the mounting table 2 to under the processing container 1 through a hole formed in the bottom wall of the processing container 1, and the lower end thereof is connected to a lifting mechanism 24. By the lifting mechanism 24 via the support member 23, the mounting table 2 moves up and down between a processing position illustrated in FIG. 1 and a conveying position illustrated by a chain two-dot line under the processing position, where the substrate W can be conveyed. A flange 25 is attached to a portion of the support member 23 that is under the processing container 1. A bellows 26 is provided between the bottom surface of the processing container 1 and the flange 25. The bellows 26 partitions the atmosphere in the processing container 1 from the outside air and expands and contracts along with the moving-up/down operation of the mounting table 2.

Three (only two are illustrated) support pins 27 are provided near the bottom surface of the processing container 1 so as to project upward from a lifting plate 27a. The support pins 27 are moved up and down by a lifting mechanism 28 provided under below the processing container 1 via the lifting plate 27a. The support pins 27 are inserted into through-holes 2a provided in the mounting table 2 that is at the conveying position, and are capable of projecting from and sinking into the upper surface of the mounting table 2. By moving up and down the support pins 27, the substrate W is passed over between the first conveying device TR1 (FIG. 5) and the mounting table 2.

The shower head 3 supplies a processing gas into the processing container 1 in the form of a shower. The shower head 3 is made of a metal and is provided so as to face the mounting table 2. The shower head 3 has approximately the same diameter as the mounting table 2. The shower head 3 includes a body part 31 and a shower plate 32. The body part 31 is fixed to the ceiling wall 14 of the processing container 1. The shower plate 32 is connected under the body part 31. A gas diffusion space 33 is formed between the body part 31 and the shower plate 32. A gas introduction hole 36 is provided in the gas diffusion space 33 so as to penetrate the center of the ceiling wall 14 and the body part 31. An annular protrusion 34 protruding downward is formed on the peripheral edge of the shower plate 32. Gas discharge holes 35 are formed in the flat portion inside the annular protrusion 34. When the mounting table 2 is at the processing position, a processing space 38 is formed between the mounting table 2 and the shower plate 32, and an annular gap 39 is formed by the upper surface of the cover member 22 and the annular protrusion 34 being close to each other.

The gas exhauster 4 exhausts gases from the interior of the processing container 1. The gas exhauster 4 has a gas exhaust pipe 41 and a gas exhaust mechanism 42. The gas exhaust pipe 41 is connected to the gas exhaust port 13b. The exhaust mechanism 42 includes a vacuum pump connected to the gas exhaust pipe 41 and a pressure control valve. In the processing, gases in the processing container 1 arrive at the gas exhaust duct 13 through the slit 13a, and are exhausted from the gas exhaust duct 13 by the gas exhaust mechanism 42 through the gas exhaust pipe 41.

The gas supply 5 supplies various processing gases to the shower head 3. The gas supply 5 includes a gas source 51 and a gas line 52. The gas source 51 includes supply sources of various processing gases, a mass flow controller, and a valve. The various processing gases include at least the gases used in the film forming method according to the aforementioned embodiment. The various gases are introduced from the gas source 51 into the gas diffusion space 33 through the gas line 52 and the gas introduction hole 36.

The film forming apparatus is a capacitively coupled plasma apparatus in which the mounting table 2 functions as a lower electrode and the shower head 3 functions as an upper electrode. The mounting table 2 is grounded. The shower head 3 is connected to the RF power supply 8.

The RF power supply 8 supplies high-frequency power (hereinafter, referred to as “RF power”) to the shower head 3. The RF power supply 8 includes an RF power source 81, a matching part 82, and a feed line 83. The RF power source 81 is a power source for generating RF power. The RF power has a frequency suitable for formation of a plasma. The frequency of the RF power is a frequency in a range from, for example, 450 KHz in a low frequency band to 2.45 GHz in the microwave band. The RF power source 81 is connected to the body part 31 via the matching part 82 and the feed line 83. The matching part 82 includes a circuit for matching a load impedance to an internal impedance of the RF power source 81. The RF power supply 8 may be configured to supply RF power to the mounting table 2.

The controller 9 is, for example, a computer, and includes a Central Processing Unit (CPU), a Random Access Memory (RAM), a Read Only Memory (ROM), an auxiliary memory device, and the like. The CPU operates based on a program stored in the ROM or the auxiliary memory device, and controls the operation of the film forming apparatus. The controller 9 may be provided inside or outside the film forming apparatus. When the controller 9 is provided outside the film forming apparatus, the controller 9 can control the film forming apparatus by a wire, wirelessly, or other such communication means.

### EXAMPLE

### Example 1

In Example 1, in order to confirm the effect of the film forming method according to the embodiment, the leakage current characteristic, which is an example of the electrical characteristic of a silicon oxide film, was measured.

First, TMA gas, which was an example of a metal catalyst gas, was supplied to a substrate, and then TPSOL gas, which was an example of a silanol-containing gas, was supplied to the substrate to form a first silicon oxide film on the substrate. Next, the silicon oxide film was reformed by a first cyclic plasma treatment. In the first cyclic plasma treatment, the step of exposing the silicon oxide film to a plasma formed from hydrogen gas and argon gas and the step of exposing the silicon oxide film to a plasma formed from argon gas were repeated twice in this order. Next, a second silicon oxide film was formed over the substrate by supplying TMA gas and then TPSOL gas to the substrate. Next, the silicon oxide film was reformed by a second cyclic plasma treatment. In the second cyclic plasma treatment, the step of exposing the silicon oxide film to plasma formed from hydrogen gas and argon gas and the step of exposing the silicon oxide film to plasma formed from argon gas were repeated three times in this order. In the first and second cyclic plasma treatment, the time taken per the step of exposing the silicon oxide film to plasma formed from hydrogen gas and argon gas was fixed to 15 seconds. The time taken per the step of exposing the silicon oxide film to plasma formed from argon gas was fixed to 15 seconds.

For comparison, a silicon oxide film was formed by changing the first and second cyclic plasma treatment to hydrogen plasma treatment without changing other conditions. In the hydrogen plasma treatment, a step of exposing the silicon oxide film to a plasma formed from hydrogen gas and argon gas was performed. The plasma irradiation time per the step was fixed to 90 seconds.

Next, the film thickness and the leakage current density of the silicon oxide film formed on the substrate were measured. The film thickness was measured using a spectroscopic ellipsometer. The leakage current density was measured using a mercury probe. A comparison was made based on the density of a current flowing through the silicon oxide film when an electric field of 5 MV/cm was applied to the silicon oxide film. The electric field was determined by dividing the applied voltage by the film thickness. The current density was determined by dividing a current measured when a voltage was applied by the electrode area of the mercury probe.

In Example 1, the silicon oxide film thickness was changed by changing the silanol-containing gas supply time, and the leakage current densities of silicon oxide films having different film thicknesses were measured.

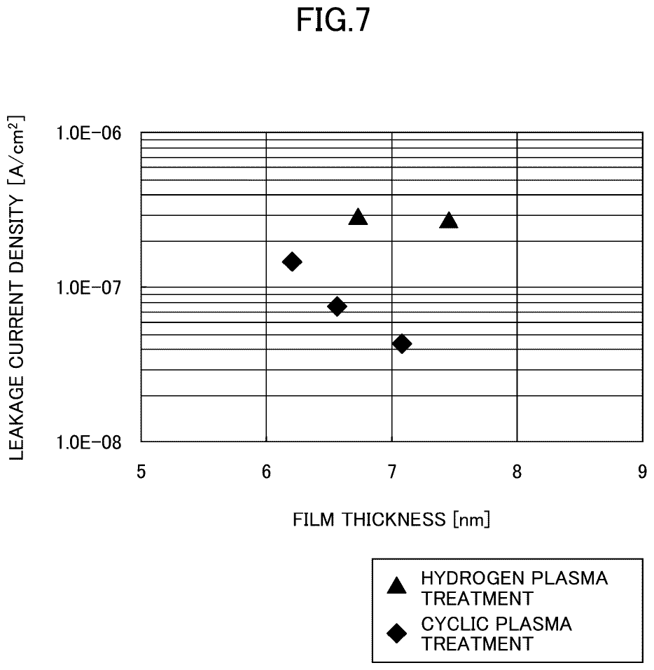

FIG. 7 is a drawing illustrating the measurement results of the leakage currents of the silicon oxide films. In FIG. 7, the horizontal axis indicates the film thickness [nm] of the silicon oxide film, and the vertical axis indicates the leakage current density [A/cm²] of the silicon oxide film. In FIG. 7, the diamond marks indicate the leakage current densities of the silicon oxide films subjected to the cyclic plasma treatment, and the triangle marks indicate the leakage current densities of the silicon oxide films subjected to the hydrogen plasma treatment.

As illustrated in FIG. 7, the leakage current densities of the silicon oxide films subjected to the cyclic plasma treatment were from 4.4×10⁻⁸ A/cm² to 1.5×10⁻⁷ A/cm². In contrast, the leakage current densities of the silicon oxide films subjected to the hydrogen plasma treatment were from 2.8×10⁻⁷ A/cm² to 2.9×10⁻⁷ A/cm². This result indicates that the leakage current densities of the silicon oxide films subjected to the cyclic plasma treatment were smaller than that of the silicon oxide films subjected to the hydrogen plasma treatment.

### Example 2

In Example 2, the infrared absorption spectra of the silicon oxide films were measured in order to clarify the mechanism behind the changes in the leakage current characteristics of the silicon oxide films.

First, a silicon oxide film subjected to cyclic plasma treatment, a silicon oxide film subjected to hydrogen plasma treatment, and a silicon oxide film subjected to neither cyclic plasma treatment nor hydrogen plasma treatment were prepared. The silicon oxide film subjected to neither cyclic plasma treatment nor hydrogen plasma treatment is hereinafter referred to as an untreated silicon oxide film.

Next, the infrared absorption spectra of the prepared silicon oxide films were measured. A Fourier Transform Infrared Spectrophotometer was used to measure the infrared absorption spectra.

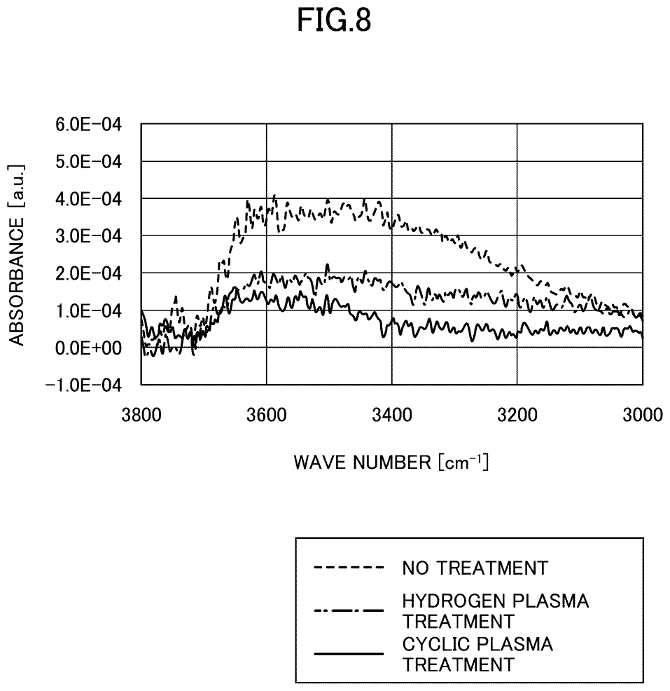

FIGS. 8 to 10 are drawings illustrating the measurement results of the infrared absorption spectra of the silicon oxide films. In FIGS. 8 to 10, the horizontal axis represents the wave number [cm⁻¹], and the vertical axis represents the absorbance [a.u.]. In FIGS. 8 to 10, the solid line indicates the absorbance of the silicon oxide film subjected to cyclic plasma treatment, the dashed line indicates the absorbance of the silicon oxide film subjected to hydrogen plasma treatment, and the broken line indicates the absorbance of the untreated silicon oxide film.

In FIG. 8, the infrared absorption at the wave number of 3,500 cm⁻¹ to 3,700 cm⁻¹ is due to Si—OH bonds. As illustrated in FIG. 8, the silicon oxide film subjected to cyclic plasma treatment and the silicon oxide film subjected to hydrogen plasma treatment have a lower infrared absorption than the untreated silicon oxide film at the wave number of 3,500 cm⁻¹ to 3,700 cm⁻¹ is smaller. From this result, it is considered possible to remove Si-OH bonds by subjecting the silicon oxide film to cyclic plasma treatment or hydrogen plasma treatment.

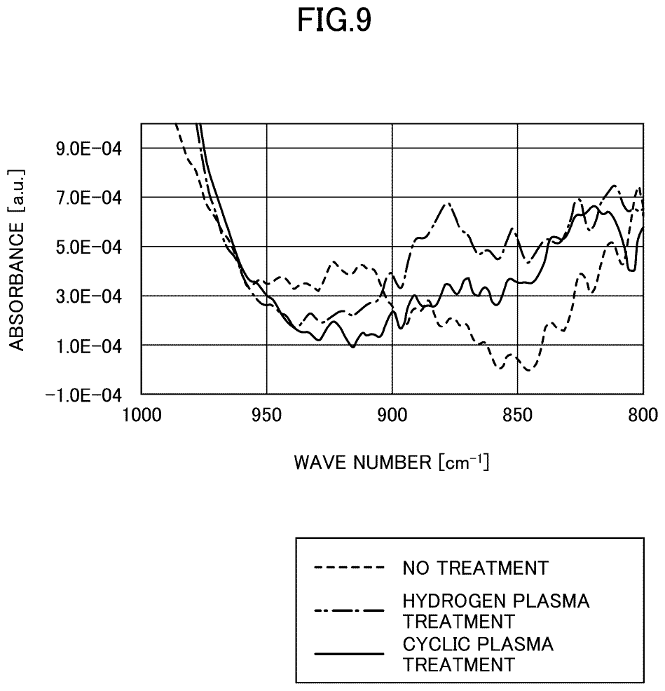

In FIG. 9, the infrared absorption at the wave number of 890 cm⁻¹ is due to the bending vibration of H—Si≡O₃ bonds. As illustrated in FIG. 9, the silicon oxide film subjected to hydrogen plasma treatment has a higher infrared absorption than the untreated silicon oxide film at the wave number of 890 cm⁻¹. From this result, it is considered that the hydrogen defects were generated in the silicon oxide film by the hydrogen plasma treatment on the silicon oxide film. On the other hand, the silicon oxide film subjected to cyclic plasma treatment has a lower infrared absorption than the silicon oxide film subjected to hydrogen plasma treatment at the wave number of 890 cm⁻¹. From this result, it is considered possible to remove hydrogen defects generated by exposure to a plasma formed from hydrogen gas and argon gas, by exposing the silicon oxide film to a plasma formed from argon gas after exposure to the plasma formed from hydrogen gas and argon gas.

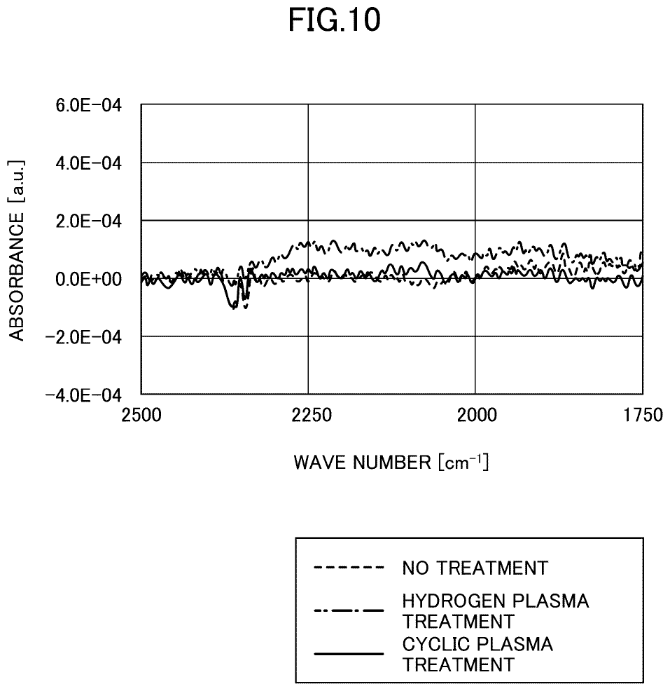

In FIG. 10, the infrared absorption at the wave number of 2,250 cm⁻¹ is due to the stretching vibration of H—Si≡O₃. As illustrated in FIG. 10, the silicon oxide film subjected to hydrogen plasma treatment has a higher infrared absorption than the untreated silicon oxide film at the wave number of 2,250 cm⁻¹. From this result, it is considered that hydrogen defects were generated in the silicon oxide film by hydrogen plasma treatment. On the other hand, the silicon oxide film subjected to cyclic plasma treatment has a lower infrared absorption than the silicon oxide film subjected to hydrogen plasma treatment at the wave number of 2,250 cm⁻¹. From this result, it is considered possible to remove hydrogen defects generated by exposure to a plasma formed from hydrogen gas and argon gas, by exposing the silicon oxide film to a plasma formed from argon gas after exposure to the plasma formed from hydrogen gas and argon gas.

From the results illustrated in FIGS. 8 to 10, it is considered possible to reduce both Si—OH bonds and hydrogen defects by subjecting the silicon oxide film to cyclic plasma treatment, resulting in a lower leakage current density of the silicon oxide film.

The presently disclosed embodiments should be considered exemplary and non-limiting in all respects. Various omissions, substitutions, and modifications are applicable to the foregoing embodiments without departing from the scope and spirit of the appended claims.

What is claimed is:

1. A film forming method for forming a silicon oxide film on a substrate, the film forming method comprising:
(a) preparing a substrate having on a surface thereof a first region where an insulating film is exposed and a second region where a conductive film is exposed;
(b) selectively forming an inhibiting layer for inhibiting formation of the silicon oxide film on the second region;
(c) forming the silicon oxide film on the first region while inhibiting formation of the silicon oxide film on the second region by the inhibiting layer; and
(d) reforming the silicon oxide film formed on the first region;
wherein (c) includes:
(c1) supplying a metal catalyst gas to the surface and adsorbing the metal catalyst gas to the first region; and
(c2) supplying a silanol-containing gas to the surface to react the silanol-containing gas with the metal catalyst gas adsorbed to the first region to form the silicon oxide film, and
wherein (d) includes:
(d1) exposing the surface to a plasma formed from a first gas containing hydrogen gas; and
(d2) exposing the surface to the plasma formed from a second gas containing no hydrogen gas and containing an inert gas.

2. The film forming method according to claim 1.
wherein in (d), a cycle including (d1) and (d2) is performed a plurality of times.

3. The film forming method according to claim 1,
wherein the plasma is maintained when switching between (d1) and (d2).

4. The film forming method according to claim 1,
wherein the plasma is stopped when switching between (d1) and (d2).

5. The film forming method according to claim 1,
wherein the first gas contains an inert gas.

6. The film forming method according to claim 5,
wherein supply of the inert gas is maintained when switching between the (d1) and the (d2).

7. The film forming method according to claim 1,
wherein in (c), a cycle including (c1) and (c2) is performed a plurality of times.

8. The film forming method according to claim 1,
wherein a cycle including (c) and (d) is performed a plurality of times.

9. The film forming method according to claim 8,
wherein a cycle further including (b) is performed a plurality of times.

10. The film forming method according to claim 1,
wherein the inhibiting layer is formed of a self-assembled monolayer.

11. The film forming method according to claim 1,
wherein the metal catalyst gas is TMA gas.

12. The film forming method according to claim 1,
wherein the silanol-containing gas is TPSOL gas.

13. A film forming apparatus for forming a silicon oxide film on a substrate, the film forming apparatus comprising:
a processing container;
a gas supply configured to supply a gas into the processing container; and
a controller,
wherein the controller is configured to control the gas supply to perform:
(a) preparing a substrate having on a surface thereof a first region where an insulating film is exposed and a second region where a conductive film is exposed;
(b) selectively forming an inhibiting layer for inhibiting formation of the silicon oxide film on the second region;
(c) forming the silicon oxide film on the first region while inhibiting formation of the silicon oxide film on the second region by the inhibiting layer; and
(d) reforming the silicon oxide film formed on the first region,
wherein (c) includes:
(c1) supplying a metal catalyst gas to the surface and adsorbing the metal catalyst gas to the first region; and
(c2) supplying a silanol-containing gas to the surface to react the silanol-containing gas with the metal catalyst gas adsorbed to the first region to form the silicon oxide film, and
Wherein (d) includes:
(d1) exposing the surface to a plasma formed from a first gas containing hydrogen gas; and
(d2) exposing the surface to the plasma formed from a second gas containing no hydrogen gas and containing an inert gas.
